(19) United States
(12) Patent Application Publication
(10) Pub. No.: US 2017/0104177 A1
(43) Pub. Date: Apr. 13, 2017

(54) ORGANIC ELECTRONIC DEVICE SEALING MEMBER

(71) Applicant: FUJIFILM Corporation, Tokyo (JP)

(72) Inventor: Yuichiro ITAI, Minami-ashigara-shi (JP)

(73) Assignee: FUJIFILM Corporation, Tokyo (JP)

(21) Appl. No.: 15/384,792

(22) Filed: Dec. 20, 2016

Related U.S. Application Data
(63) Continuation of application No. PCT/JP2015/068290, filed on Jun. 25, 2015.

(30) Foreign Application Priority Data
Jun. 27, 2014 (JP) 2014-133004

(51) Int. Cl. H01L 51/52; C09J 135/02; H01L 51/00; C09J 7/02

(52) U.S. Cl. CPC H01L 51/5246; H01L 51/5256; C09J 7/0267; C09J 7/0246; C09J 135/02; H01L 51/0043; H01L 51/004; C09J 2203/326; C09J 2205/114; C09J 2433/00; C09J 2433/006

(57) ABSTRACT

The present invention provides an organic electronic device sealing member including a gas barrier film including an inorganic layer and an organic layer and an adhesive layer, in which the adhesive layer includes a polymerizable compound and an organic metal compound, an average secondary particle diameter of the organic metal compound is 100 nm or less, and the organic metal compound has a structure represented by Formula I: -[M(OR)—O]n-. In Formula I, M represents a trivalent metal atom, R represents a substituted or unsubstituted alkyl group, a substituted or unsubstituted aryl group, or a substituted or unsubstituted alkylcarbonyl group, n represents an integer of 2 to 6, two or more R's may be the same as or different from each other, and a first [M(OR)—O] and an n-th [M(OR)—O] are bonded to each other. The organic electronic device sealing member of the present invention is capable of drying an organic electronic element to a higher degree and has low haze.

### CROSS-REFERENCE TO RELATED APPLICATIONS

This application is a continuation of PCT International Application No. PCT/JP2015/068290 filed on Jun. 25, 2015, which claims priority under 35 U.S.C. §119 (a) to Japanese Patent Application No. 2014-133004 filed on Jun. 27, 2014. The entire content of each of the above applications is incorporated herein by reference.

### BACKGROUND OF THE INVENTION

1. Field of the Invention

The present invention relates to an organic electronic device sealing member.

2. Description of the Related Art

In many organic electroluminescent devices, organic electroluminescent elements can be sealed by bonding a sealing member to a substrate provided with an organic electroluminescent element with a pressure sensitive adhesive. Using a gas barrier film which is lightweight and has impact resistance as a substrate or a sealing member has been proposed (for example, refer to JP2012-109255A or JP2005-251500A). JP2009-79230A discloses a pressure sensitive adhesive that can be used in a case of carrying out solid filling type sealing of an organic electroluminescent device of a top emission type. In addition, JP2005-298598A discloses a moisture absorbing agent for an organic EL element including an ultraviolet curing agent and a moisture absorbing substance.

### SUMMARY OF THE INVENTION

Water, oxygen, and the like that are sealed inside a substrate and a sealing member composed of glass and a gas barrier film are not easily discharged to the outside and oxygen and water included in a pressure sensitive adhesive degrade an organic electroluminescent element. In consideration of this point, the present inventors have examined incorporating the moisture absorbing substance described in JP2005-298598A, as a drying agent, into a pressure sensitive adhesive at the time of sealing. However, in the gas barrier film having a configuration in which an organic layer and an inorganic layer are laminated and a pressure sensitive adhesive including the above drying agent are used in combination, a sufficient drying effect cannot be obtained and the haze increases. Thus, there may be a case in which a sufficient transparency for an organic electroluminescent device of a top emission type or the like to be used is not obtained.

An object of the present invention is to provide a member capable of drying an organic electronic element to a higher degree and having low haze, as an organic electronic device sealing member including a gas barrier film including an organic layer and an inorganic layer.

As a result of examination conducted by the present inventors, it has been found that in the case of using a gas barrier film and a drying agent in combination, the drying agent particles do not enter specific minute defect portions in the inorganic layer in the gas barrier film including an organic layer and an inorganic layer so as to compensate for the defects and the drying agent particles aggregate in portions other than the defect portions. It is thought that due to this aggregation, a sufficient drying effect cannot be obtained and also the drying agent is not sufficiently dispersed, which causes an increase in haze. The present inventors have further conducted intensive examinations regarding the composition of a pressure sensitive adhesive and the composition of a gas barrier film capable of preventing aggregation and thus completed the present invention.

That is, the present invention provides the following [1] to [12].

[1] An organic electronic device sealing member comprising:

a gas barrier film; and

an adhesive layer,

in which the gas barrier film includes a barrier laminate including at least one inorganic layer and at least one organic layer, and the adhesive layer includes a polymerizable compound and an organic metal compound,

an average secondary particle diameter of the organic metal compound is 100 nm or less, and

the organic metal compound has a structure represented by Formula I:

-[M(OR)—O]n- Formula I

in Formula I, M represents a trivalent metal atom, R represents a substituted or unsubstituted alkyl group, a substituted or unsubstituted aryl group, or a substituted or unsubstituted alkylcarbonyl group, n represents an integer of 2 to 6, two or more R's may be the same as or different from each other, and a first [M(OR)—O] and an n-th [M(OR)—O] are bonded to each other.

[2] The organic electronic device sealing member according to [1],

in which n R's are all the same.

[3] The organic electronic device sealing member according to [1] or [2],

in which M is Al.

[4] The organic electronic device sealing member according to any one of [1] to [3],

in which the polymerizable compound is (meth)acrylate.

[5] The organic electronic device sealing member according to any one of [1] to [4],

in which the gas barrier film includes a substrate film, and the barrier laminate is arranged on the side of the substrate film close to the adhesive layer.

[6] The organic electronic device sealing member according to any one of [1] to [5],

in which the at least one inorganic layer is in direct contact with the adhesive layer.

[7] The organic electronic device sealing member according to any one of [1] to [6],

in which an organic layer closest to the adhesive layer is a layer formed by curing a polymerizable composition including (meth)acrylate.

[8] The organic electronic device sealing member according to any one of [1] to [7],

in which R forms ROH having an Sp value in a range of 8.5 to 12 (cal/cm³)^{1/2}.

[9] The organic electronic device sealing member according to any one of [1] to [8],

in which an Sp value of the polymerizable compound is 8.5 to 12 (cal/cm³)^{1/2}.

[10] The organic electronic device sealing member according to any one of [1] to [9],

in which a difference between the Sp value of ROH that R forms and the Sp value of the polymerizable compound is 2 (cal/cm³)^{1/2} or less.

[11] The organic electronic device sealing member according to any one of [1] to [10],

in which the adhesive layer is a layer composed of a polymerizable composition including the polymerizable compound, the organic metal compound, and a solvent, and an Sp value of the solvent is 8.5 to 12 (cal/cm³)^{1/2}.

[12] The organic electronic device sealing member according to any one of [1] to [11],

in which the adhesive layer is a layer composed of a polymerizable composition including the polymerizable compound, the organic metal compound, and a solvent, and both a difference between the Sp value of the solvent and the Sp value of ROH that R forms and a difference between the Sp value of the solvent and the Sp value of the polymerizable compound are 2 (cal/cm³)^{1/2} or less.

According to the present invention, there is provided an organic electronic device sealing member capable of drying an organic electronic element to a higher degree and having low haze, as an organic electronic device sealing member including a gas barrier film including an organic layer and an inorganic layer. In an organic electronic device using the organic electronic device sealing member of the present invention, the organic electronic element can be dried to a higher degree. In addition, transparency enough to be used for an organic electroluminescent device of a top emission type or the like can be maintained.

### DESCRIPTION OF THE PREFERRED EMBODIMENTS

Hereinafter, the contents of the present invention will be described in detail.

Incidentally, the numerical range which is shown by “to” using the present specification means the range including the numerical values described before and after the “to” as the lower limit and the upper limit, respectively. In the present specification, a description of “(meth)acrylate” represents the meaning of “either or both of acrylate and methacrylate”. The same is applied to “(Meth)acryloyl” group and the like. Further, in the present specification, the term “organic EL element” used means “organic electroluminescent element”.

In the present specification, the Sp value means a solubility parameter. The solubility parameter (Sp value) can be obtained by an OKITSU method. The OKITSU method is specifically described in Journal of the Adhesion Society of Japan Vol. 29, No. 6 (1993), pp. 249 to 259. The Sp value used in the present specification is expressed by unit of (cal/cm³)^{1/2} and 1 (cal/cm³)^{1/2} corresponds to about 2.05 (MPa)^{1/2}.

<Organic Electronic Device Sealing Member>

An organic electronic device sealing member is a member that is bonded to a substrate provided with an organic electronic element on the surface thereof and can be used as a member for sealing the organic electronic element with the substrate. In the present specification, the organic electronic device sealing member is sometimes simply referred to as a sealing member.

The shape of the organic electronic device sealing member is not particularly limited and a normal film shape may be adopted.

The organic electronic device sealing member includes a gas barrier film and an adhesive layer. It is preferable that the organic electronic device sealing member includes the adhesive layer as the outermost surface. In addition, the organic electronic device sealing member may have a protective film for protecting the adhesive layer as the outermost layer adjacent to the adhesive layer before the member is used for sealing. As the protective film, a PET film or the like can be used.

The thickness of the organic electronic device sealing member is preferably 50 μm to 600 μm and more preferably 100 μm to 300 μm excluding the thickness of the protective film.

The haze value of the organic electronic device sealing member is preferably 0 to 5 and more preferably 0 to 3. Since the dispersibility of a drying agent is good in the adhesive layer, the organic electronic device sealing member of the present invention has a low haze value. In addition, the organic electronic device sealing member is applied to an organic electronic device and can maintain a low haze value even after the adhesive layer is cured.

In the present specification, the term “haze value” means a value measured using a haze meter MODEL 1001 DP manufactured by Nippon Denshoku Industries Co., Ltd.).

Theoretically, the haze value means a value represented by the following expression.

(Scattering transmittance of visible light)/(Scattering transmittance of visible light+Direct transmittance of visible light)×100%

The scattering transmittance is a value that can be calculated by subtracting the direct transmittance from the omnidirectional transmittance that can be obtained using a spectrophotometer and an integrating sphere unit. In the case in which the direct transmittance is based on a value measured using an integrating sphere unit, the direct transmittance is a transmittance at 0°. The visible light means light having a wavelength of 380 to 780 nm.

<Pressure Sensitive Adhesive Layer>

The adhesive layer functions as a layer for bonding the organic electronic device sealing member to the substrate or the organic electronic element.

The adhesive layer includes a polymerizable compound and an organic metal compound. The adhesive layer may include other components such as a polymerization initiator, as required. The adhesive layer is cured by the action of ultraviolet rays or heat and may have a function of bonding the gas barrier film in the organic electronic device sealing member to the substrate.

The adhesive layer can be formed by, for example, applying the polymerizable composition including the polymerizable compound and the organic metal compound to the surface of the gas barrier film. The polymerizable composition may include other components such as a polymerization initiator. The polymerizable composition may include a solvent and the adhesive layer may be formed by applying a polymerizable composition including a solvent to the surface of the gas barrier film and removing the solvent by drying.

The thickness of the adhesive layer is preferably 1 μm to 200 μm and more preferably 5 μm to 50

(Polymerizable Compound)

As the polymerizable compound, a (meth)acrylate compound or an epoxy compound can be preferably used.

In the case in which the organic electronic device sealing member is bonded to the substrate by ultraviolet rays, it is preferable to use a (meth)acrylate compound, and in the case in which the organic electronic device sealing member is bonded to the substrate by heating, it is preferable to use an epoxy compound.

Examples of the (meth)acrylate compound include compounds described in paragraphs 0038 to 0041 of JP2013-108057A. As examples of the (meth)acrylate compound, both polyfunctional (meth)acrylate and monofunctional (meth)acrylate may be used and polyfunctional (meth)acrylate and monofunctional (meth)acrylate may be used in combination. Specific examples of the (meth)acrylate compound include dipentaerythritol hexaacrylate (DPHA: Sp value: 10.1), epoxy acrylate:4-hydroxybutyl acrylate glycidyl ether (Sp value: 10.3), BISCOATE, manufactured by Osaka Organic Chemical Industry Ltd., and A-9300 and TMPT, manufactured by SHIN-NAKAMURA CHEMICAL CO. LTD.

As the epoxy compound, both an epoxy compound having an aromatic ring and an alicyclic epoxy compound can be used.

The epoxy compound having an aromatic ring is not particularly limited as long as the compound has an aromatic ring and an epoxy group in the structure thereof. Examples thereof include novolac type epoxy monomers such as phenol novolac type epoxy monomers, cresol novolac type epoxy monomers, bisphenol novolac type epoxy monomers, trisphenol novolac type epoxy monomers, and dicyclopentadiene novolac type epoxy monomers; and bisphenol type epoxy monomers such as bisphenol A type epoxy monomers, bisphenol F type epoxy monomer, 2,2′-diallyl bisphenol A type epoxy monomers, bisphenol S type epoxy monomers, and polyoxypropylene bisphenol A type epoxy. Among these, bisphenol A type epoxy monomers and bisphenol F type epoxy monomers are suitably used.

Specific examples of the alicyclic epoxy compound include compounds represented by Formulae (1), (2), and (3) below.

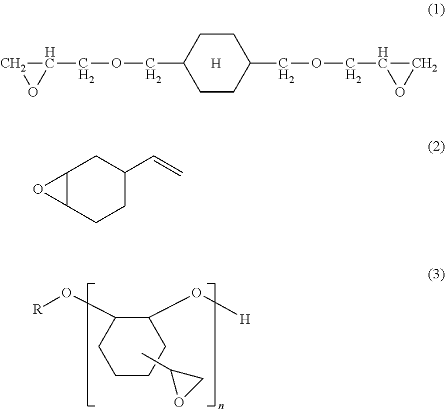

In Formula (3), R represents hydrogen or a linear or branched alkyl group having 1 to 12 carbon atoms, and n represents an integer of 1 to 30.

Among the compounds represented by Formula (1) above, an example of a commercially available compound includes “DME-100” manufactured by New Japan Chemical Co., Ltd.

Among the compounds represented by Formula (2) above, an example of a commercially available compound includes “CELLOXIDE 2000” manufactured by DAICEL CORPORATION.

Among the compounds represented by Formula (3) above, an example of a commercially available compound includes “EHPE 3150” manufactured by DAICEL CORPORATION.

Preferable examples of the epoxy compound include a compound having two or more alicyclic skeletons. Preferable examples of the epoxy compound having two or more alicyclic skeletons include at least one selected from the group consisting of compounds represented by Formulae (4), (5), and (6) below. These compounds have excellent light resistance and excellent moisture resistance.

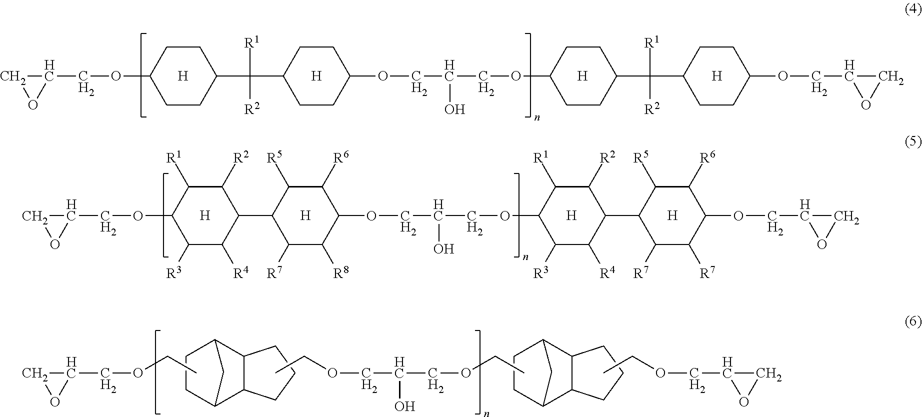

In Formula (4), n represents an integer of 0 to 20. R¹ and R² represent hydrogen or a linear or branched alkyl group having 1 to 12 carbon atoms and may be the same as or different from each other.

In Formula (5), n represents an integer of 0 to 20. R¹ to R⁸ represent hydrogen or a linear or branched alkyl group having 1 to 12 carbon atoms and may be the same as or different from each other.

In Formula (6), n represents an integer of 0 to 20.

Among the compounds represented by Formula (4) above, R¹ and R² more preferably represent hydrogen or a methyl group. By using these compounds, the curable adhesive of the present invention has excellent light resistance and moisture resistance. Among these, R¹ and R² are particularly preferably hydrogen.

The epoxy compounds may be used alone or as a mixture of two or more thereof.

The Sp value of the polymerizable compound is preferably 8.5 to 12 (cal/cm³)^{1/2}, more preferably 9 to 11 (cal/cm³)^{1/2}, and still more preferably 10 to 10.5 (cal/cm³)^{1/2}. The Sp value will be described later.

(Organic Metal Compound)

The organic metal compound is a compound having a structure represented by Formula I.

-[M(OR)—O]n- Formula I

In Formula I, M represents a trivalent metal atom, R represents a substituted or unsubstituted alkyl group, a substituted or unsubstituted aryl group, or a substituted or unsubstituted alkylcarbonyl group, n represents an integer of 2 to 6, two or more R's may be the same as or different from each other, and a first [M(OR)—O] and an n-th [M(OR)—O] are bonded to each other.

In the present specification, examples of the substituent at the time of “substitution” when referring to “substituted or unsubstituted” include an alkyl group, an alkenyl group, an alkynyl group, an aryl group, an alkoxyl group, a carboxyl group, and an amino group. The number of substituents, and the type and the substitution position thereof are not particularly limited and in the case in which two or three or more substituents are present, these substituents may be the same as or different from each other.

The alkyl group may be a linear or branched alkyl group. The number of carbon atoms of the alkyl group is preferably 1 to 30, more preferably 6 to 25, and particularly preferably 12 to 20. Examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a linear or branched heptyl group, an octyl group, a nonyl group, a decyl group, an undecyl group, and a dodecyl group. The description regarding the alkyl group is the same as the description of the alkyl group in the alkylcarbonyl group.

Examples of the aryl group include a phenyl group and a naphthyl group.

Plural R's present in the compound represented by Formula I may be the same as or different from each other and are preferably the same. n represents an integer of 2 to 6, preferably 3 to 5, and more preferably 3.

In Formula I, M represents a trivalent metal atom. Examples of such a metal atom include Group 4 elements and Group 13 elements in the IUPAC periodic table. Specifically, Al, B, Ti, Zr, and the like may be exemplified. Among these, from the viewpoint of excellent hygroscopicity and oxygen absorbing properties or from the viewpoint of being capable of maintaining transparency without coloration after decomposition through capturing of moisture and oxygen, Al is more preferable.

In Formula I, the first [M(OR)—O] and the n-th [M(OR)—O] are bonded to each other. That is, the first [M(OR)—O] and the n-th [M(OR)—O] are bonded to each other by a single bond represented in Formula. As a result, the compound represented by Formula I has a cyclic structure.

Specific examples of the compound represented by Formula I above include aluminum oxide 2-ethylhexanoate (OLIEPE AOO, manufactured by Hope Chemical Co., Ltd.), aluminum oxide isopropylate (ALGOMAR 7, manufactured by Kawaken Fine Chemicals Co., Ltd.), aluminum oxide stearate (OLIEPE AOS, manufactured by Hope Chemical Co., Ltd.), and aluminum oxide ethylate.

In the adhesive layer, the average secondary particle diameter of the organic metal compound is 100 nm or less.

The secondary particle diameter is defined as the size of aggregates when the primary particles thereof aggregate in a certain state (environment) with respect to the primary particle diameter defined as a particle diameter in a state in which fine particles are ideally dispersed. In a dispersion in which general fine particles are contained, the fine particles aggregate to have a predetermined size in many cases. In addition, the average secondary particle diameter may be measured by a dynamic light scattering method, a laser diffraction method, an image imaging method, and the like. However, the value of average secondary particle diameter defined in the present specification is obtained based on a dynamic light scattering method.

The average secondary particle diameter of the organic metal compound is preferably 20 to 100 nm, more preferably 30 to 90 nm, and still more preferably 40 to 80 nm. When the average secondary particle diameter of the organic metal compound in the adhesive layer of the sealing member of the present invention is 100 nm or less, a low haze state can be maintained.

The organic metal compound represented by Formula I is subjected to hydrolysis to obtain alcohol represented by ROH. It is preferable that R is selected so that the Sp value of ROH is in a range of 8 to 12 (cal/cm³)^{1/2}. For example, regarding the Sp value of ROH, the Sp value of aluminum oxide 2-ethylhexanoate is 8.8, the Sp value of aluminum oxide isopropylate is 11.5, the Sp value of aluminum oxide stearate is 8.4, and the Sp value of aluminum oxide ethylate is 12.6.

The dispersibility of the organic metal compound having R thus selected is good in the composition and the average secondary particle diameter can be set to be in the above range of 100 nm or less.

The difference between the Sp value of ROH and the SP value of the polymerizable compound is preferably 2 (cal/cm³)^{1/2} or less, more preferably 1.7 (cal/cm³)^{1/2} or less, and still more preferably 1.5 (cal/cm³)¹¹² or less.

(Polymerization Initiator)

The polymerizable composition used to form the adhesive layer may include a polymerization initiator. As the polymerization initiator, according to the curing condition of the adhesive layer, a photopolymerization initiator or a thermal polymerization initiator is used.

As the photopolymerization initiator, both a radical photopolymerization initiator and a photocationic polymerization initiator may be used. In the case in which the polymerizable compound is an epoxy compound, it is preferable to use a photocationic polymerization initiator, and in the case in which the polymerizable compound is a (meth)acrylate compound, it is preferable to use a radical photopolymerization initiator.

The photocationic polymerization initiator is not particularly limited and may be of an ionic photoacid generation type or a nonionic photoacid generation type.

The ionic photoacid generation type photocationic polymerization initiator is not particularly limited and examples thereof include onium salts such as aromatic diazonium salts, halonium salts, and aromatic sulfonium salts, and organic metal complexes such as iron-allene complexes, titanocene complexes, and aryl silanol-aluminum complexes. These photocationic polymerization initiators may be used alone or in combination of two or more thereof.

Specific examples of the ionic photoacid generation type photocationic polymerization initiator include “ADECAOPTOMER SP150” and “ADECAOPTOMER SP170” (all manufactured by Asahi Denka Kogyo K.K.).

The photocationic polymerization initiator is not particularly limited and is preferably a cationic photopolymerization initiator that absorbs light having a wavelength of 300 nm or more and more preferably a photocationic polymerization initiator that absorbs light having a wavelength of 300 to 400 nm.

The nonionic photoacid generation type photocationic polymerization initiator is not particularly limited and examples thereof include nitrobenzyl ester, sulfonic acid derivatives, phosphate esters, phenolsulfonate esters, diazonaphthoquinone, and N-hydroxyimidosulfonate.

In the case of using the cationic photopolymerization initiator, it is preferable that the adhesive layer is cured at 100° C. or lower.

Examples of the radical photopolymerization initiator include IRGACURE series (for example, IRGACURE 651, IRGACURE 754, IRGACURE 184, IRGACURE 2959, IRGACURE 907, IRGACURE 369, IRGACURE 379, and IRGACURE 819), DAROCURE series (for example, DAROCURE TPO, and DAROCURE 1173), QUANTACURE PDO, all of which are made to be commercially available by BASF Japan Ltd., and ESACURE series (for example, ESACURE TZM, ESACURE TZT, and ESACURE KT046), and ESACURE KIP series, both of which are made to be commercially available by Lamberti S. p., and the like.

Examples of the thermal polymerization initiator include oil soluble organic azo compounds such as 2,2′-azobis isobutyronitrile (available as V-60 manufactured by Wako Pure Chemical Industries, Ltd. or AIBN manufactured by Otsuka Chemical Co., Ltd.), 2,2′-azobis-(2,4-dimethylvaleronitrile) (available as V-65 manufactured by Wako Pure Chemical Industries, Ltd. or ADVN manufactured by Otsuka Chemical Co., Ltd.), and 2,2′-azobis-(4-methoxy-2,4-dimethylvaleronitrile) (available as V-70 manufactured by Wako Pure Chemical Industries, Ltd.) or water soluble organic azo compounds.

The amount of the polymerization initiator included in the adhesive layer is preferable 0.001 or more and more preferably 0.005 to 0.05 with respect to the molar amount of the polymerizable compound in terms of a molar ratio.

(Solvent)

The polymerizable composition for forming the adhesive layer may include a solvent. Examples of the solvent include alcohols, ketones, esters, amides, ethers, ether esters, aliphatic hydrocarbons, and halogenated hydrocarbons. Specific examples thereof include alcohols (for example, propanol, butanol, benzyl alcohol, ethylene glycol, propylene glycol, and ethylene glycol monoacetate), ketones (for example, methyl ethyl ketone, methyl isobutyl ketone, cyclohexanone, and methylcyclohexanone), esters (for example, methyl acetate, ethyl acetate, propyl acetate, butyl acetate, ethyl formate, propyl formate, butyl formate, and ethyl lactate), aliphatic hydrocarbons (for example, hexane and cyclohexane), halogenated hydrocarbons (for example, methylchloroform), aromatic hydrocarbons (for example, benzene, toluene, xylene, and ethylbenzene), amides (for example, dimethylformamide, dimethylacetatamide, and n-methylpyrrolidone), ethers (for example, dioxane, tetrahydrofuran, ethylene glycol dimethyl ether, and propylene glycol dimethyl ether), and ether alcohols (for example, 1-methoxy-2-propanol, ethyl cellosolve, and methyl carbinol). These solvents may be used alone or in combination of two or more thereof. Among these, aromatic hydrocarbons and ketones are preferable, and toluene, xylene, methyl ethyl ketone, methyl isobutyl ketone, and cyclohexanone are more preferable.

The Sp value of the solvent is preferably 8.5 to 12 (cal/cm³)^{1/2} and more preferably 9 to 10.5 (cal/cm³)^{1/2}.

The difference between the Sp value of the solvent and the Sp value of the ROH is preferably 2 (cal/cm³)^{1/2} or less and more preferably 1.7 (cal/cm³)^{1/2} or less. In addition, the between the Sp value of the solvent and the Sp value of the polymerizable compound is preferably 2 (cal/cm³)^{1/2} or less and more preferably 1.7 (cal/cm³)^{1/2} or less. Further, both the difference between the Sp value of the solvent and the Sp value of the ROH and the difference between the Sp value of the solvent and the Sp value of the polymerizable compound are preferably 2 (cal/cm³)^{1/2} or less. By using the solvent having such an Sp value, dispersibility can be improved in the composition of the organic metal compound. Examples of the solvent having an Sp value of 8.5 (cal/cm³)^{1/2} or more and 12 (cal/cm³)^{1/2} or less include alcohols such as isopropanol, 1-propanol, butanol, benzyl alcohol, and propylene glycol, ketones such as acetone, methyl ethyl ketone (Sp value: 9.3), methyl isobutyl ketone, cyclohexanone, and methyl cyclohexanone, esters such as methyl acetate, ethyl acetate, acetic acid propyl, butyl acetate, ethyl formate, formic acid propyl, formic acid butyl, and propylene glycol monomethyl ether acetate, aromatic hydrocarbons such as benzene, toluene, xylene, and ethylbenzene, amides such as dimethyl formamide and dimethyl acetamide, ethers such as dioxane and tetrahydrofuran, and ether alcohols such as cellosolve, diethylene glycol monomethyl ether, and propylene glycol monomethyl ether.

(Gas Barrier Film)

The organic electronic device sealing member includes a gas barrier film. The gas barrier film functions as a layer for preventing oxygen or water from entering the side close to the adhesive layer. In addition, the gas barrier film preferably has flexibility. The gas barrier film includes a barrier laminate including an organic layer and an inorganic layer. The gas barrier film preferably includes a substrate film. The gas barrier film may have functional layers other than barrier laminate and the substrate film (for example, functional layers such as an easily adhesive layer or an easily lubricating layer). The functional layer may be arranged on any one of the surface of the barrier laminate, between the barrier laminate and the substrate film, and a surface of the substrate film on which the barrier laminate is not arranged (rear surface).

In the organic electronic device sealing member, it is preferable the gas barrier film is in direct contact with the adhesive layer by the barrier laminate. The inorganic layer may be in direct contact with the adhesive layer or the organic layer may be in direct contact with the adhesive layer. However, it is preferable that the inorganic layer is in direct contact with the adhesive layer.

(Barrier Laminate)

The barrier laminate includes at least one organic layer and at least one inorganic layer and may include two or more organic layers and two or more inorganic layers which are alternately laminated. The number of layers constituting the barrier laminate is not particularly limited and typically, 2 layers to 30 layers are preferable and 3 layers to 20 layers are more preferable. In addition, the barrier laminate may include constituent layers other than the organic layer and the inorganic layer. The thickness of the barrier laminate is preferably 0.5 μm to 10 μm and more preferably 1 μm to 5 μM.

Regarding the barrier laminate, for example, the descriptions of the barrier laminates in JP2010-200780A, JP2010-200780A, JP2010-6064A, and JP2008-221830A, and the description of the gas barrier layer in JP2009-81122A can be referred to.

(Inorganic Layer)

The inorganic layer is typically a layer of thin film composed of a metal compound. The inorganic layer may be formed by any method as long as a desired thin film can be formed by the method. For example, physical vapor-phase deposition method (PVD) such as a vapor evaporation method, a sputtering method or an ion-plating method; various chemical vapor-phase deposition method (CVD); and liquid-phase deposition method such as a plating method or a sol-gel method may be used. The component to be included in the inorganic layer is not particularly limited as long as the above performance is satisfied, and examples thereof include metal oxides, metal nitrides, metal carbides, metal oxinitrides, and metal oxycarbides. Oxides, nitrides, carbides, oxinitrides, and oxycarbides including one or more metals selected from the group consisting of Si, Al, In, Sn, Zn, Ti, Cu, Ce, and Ta can be preferably used. Among these, oxides, nitrides or oxinitrides of a metal selected from the group consisting of Si, Al, In, Sn, Zn, and Ti are preferable and metal oxides, nitrides or oxinitrides with Si (silicon) or Al (aluminum) are particularly preferable. These may contain any other element as a subsidiary component. For example, a nitride having a hydroxyl group may be employed.

As the inorganic layer, inorganic layers including Si are particularly preferable. This is because the inorganic layers including Si have higher transparency and more excellent gas barrier properties. Among these, an inorganic layer composed of silicon nitride is particularly preferable.

For example, the inorganic layer may include a hydrogen by hydrogen included in metal oxides, nitrides or oxinitrides. The hydrogen concentration in forward Rutherford scattering is preferably 30% or less.

Regarding the smoothness of the inorganic layer formed in the present invention, the average roughness of 1 μm square (Ra value) is preferably less than 3 nm and more preferably 1 nm or less.

The thickness of the inorganic layer is not particularly limited and the thickness for one layer is typically within a range of 5 to 500 nm, preferably 10 to 200 nm, and more preferably 15 to 50 nm. The inorganic layer may have a laminated structure composed of a plurality of sublayers. In this case, each sublayer may have the same composition or different compositions.

(Organic Layer)

The organic layer can be preferably formed by curing a polymerizable composition including a polymerizable compound.

The polymerizable compound used to form the organic layer in the barrier laminate is preferably a compound having an ethylenically unsaturated bond at the terminal or in the side chain and/or a compound having epoxy or oxetane at the terminal or in the side chain. As the polymerizable compound, a compound having an ethylenically unsaturated bond at the terminal end or in the side chain is particularly preferable. Examples of the compound having an ethylenically unsaturated bond at the terminal or in the side chain include (meth)acrylate compounds, acrylamide compounds, styrene compound, and maleic anhydride. Preferable are (meth)acrylate compounds and particularly preferable are acrylate compounds. Particularly, it is preferable that in the sealing member, the organic layer closest to the adhesive layer is a layer formed by curing a polymerizable composition including (meth)acrylate.

As (meth)acrylate compounds, preferred are (meth)acrylates, urethane-(meth)acrylates, polyester-(meth)acrylates, epoxy(meth)acrylates, and the like.

As styrene compounds, preferred are styrene, α-methylstyrene, 4-methylstyrene, divinylbenzene, 4-hydroxystyrene, 4-carboxystyrene, and the like.

Specifically, as (meth)acrylate compounds, compounds described in paragraphs 0024 to 0036 of JP2013-43382A or paragraphs 0036 to 0048 of JP2013-43384A can be used. In addition, polyfunctional acrylic monomers having a fluorene skeleton described in WO2013/047524, can be used.

The organic layer is preferably smooth with a high degree of film hardness. The smoothness of the organic layer is preferably a 1 μm square average roughness (Ra value) of less than 3 nm, and more preferably less than 1 nm.

The film thickness of the organic layer is not particularly limited and from the viewpoint of brittleness and light transmittance, the thickness thereof is preferably 50 nm to 5,000 nm and more preferably 200 nm to 3,500 nm.

(Substrate Film)

The gas barrier film may include a substrate film in addition to the barrier laminate. As the substrate film, a plastic film can be used. The plastic film to be used can be appropriately selected according to purposes of use. Specific examples of the plastic film include thermoplastic resins such as polyester resin, methacryl resin, methacrylic acid-maleic anhydride copolymers, polystyrene resin, transparent fluororesin, polyimide resin, fluoropolyimide resin, polyamide resin, polyamide imide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorene ring-modified polycarbonate resin, alicyclic-modified polycarbonate resin, fluorene ring-modified polyester resin, and acryloyl compounds.

The thickness of the substrate film is preferably 10 μm to 250 μm and more preferably 20 μm to 130 μm.

<Organic Electronic Device and Organic Electroluminescent Device>

Examples of an organic electronic device to which the organic electronic device sealing member of the present invention can be applied include organic electroluminescent devices, liquid crystal display element devices, thin film transistors, touch panels, electronic papers, and solar cells. The organic electronic device sealing member of the present invention can be preferably used in manufacturing an organic electroluminescent device particularly. The sealing member of the present invention has a low haze value and maintains the low haze value even after sealing (after curing the adhesive layer). Thus, the sealing member can be also preferably used for an organic electroluminescent device of a top emission type in which light is extracted from the organic electroluminescent element on the substrate to the sealing member.

The organic electroluminescent device includes a substrate, an organic electroluminescent element, and a sealing member. By sealing (closing) the organic electroluminescent element with the substrate and the sealing member, the organic electroluminescent element that easily deteriorate over time by water, oxygen or the like when being used under normal pressure is protected from deteriorating.

The organic electroluminescent device may have a structure including a portion including the substrate, the organic electroluminescent element, the adhesive layer, and the gas barrier film in this order in the thickness direction of the substrate.

(Organic Electroluminescent Element)

The organic electroluminescent element is configured to include electrodes each of which becomes a cathode and an anode and further include an organic electroluminescent layer between the two electrodes.

Regarding the electrodes in the organic electroluminescent device, either of one electrode which is arranged close to the substrate and one electrode which is arranged close to the sealing member may be a reflecting electrode and the other electrode may be a transparent electrode. It is also preferable that one electrode which is arranged close to the substrate is a reflecting electrode and the other electrode which is arranged close to the sealing member is a transparent electrode.

The organic electroluminescent layer means a layer having at least a light emitting layer, and further having respective layers of a hole transport layer, an electron transport layer, a hole blocking layer, an electron blocking layer, a hole injection layer, and an electron injection layer, as functional layers other than the light emitting layer.

Regarding materials for producing the organic electroluminescent layer, and each layer and each electrode in the organic electroluminescent layer, configurations, lamination order, and the configuration of the organic electroluminescent device, the contents of paragraphs 0081 to 0122 of JP2012-155177A can be referred to.

(Substrate)

The shape, structure, size, material, and the like of the substrate are not particularly limited and can be appropriately selected according to the purpose. For example, the shape may be a film-like shape or a plate-like shape. The structure may be a single layer structure or a laminated structure. The size can be appropriately selected according to the size of the functional laminated material or the like.

As the materials for the substrate and the sealing member, particularly, inorganic materials such as glass (such as alkali-free glass and soda lime glass), and gas barrier films are preferable. In the case in which a gas barrier film having a substrate film is used as the substrate, it is preferable that the surface of the substrate film close to the barrier laminate is arranged close to the organic electroluminescent element. The outermost surface close to the organic electroluminescent element is preferably an inorganic layer.

One preferable example is an organic electroluminescent device in which glass is used as the substrate and a gas barrier film is used as the sealing member.

The substrate may be appropriately synthesized or a commercially available product may be used.

The thickness of the substrate is preferably 300 μm to 1,000 μm and more preferably 500 μm to 800 μm in the case of using a rigid substrate such as glass as the substrate. In the case of using a film such as a gas barrier film or a flexible glass as the substrate, the thickness of the substrate is preferably 10 μm to 500 μm and more preferably 20 μm to 300 μm.

### EXAMPLES

The present invention is described with greater specificity below through Examples. The materials, amounts used, ratios, processing contents, processing procedures, and the like that are indicated in the Examples below can be suitably modified without departing from the spirit of the present invention. Accordingly, the scope of the present invention is not limited by the specific examples given below.

### Example 1

<Preparation of Gas Barrier Film>

An organic layer application composition including 100 parts by mass of a polymerizable compound (trimethylolpropane triacrylate (TMPTA), manufactured by Daicel-Cytec Corporation), a photopolymerization initiator (IRGACURE 184, manufactured by BASF Japan Ltd.), and methyl ethyl ketone (MEK) was prepared. The amount of MEK was prepared such that the film thickness after drying is 1 μm and the amount of the photopolymerization initiator was set to 3% by mass in the composition.

The obtained organic layer application composition was applied to a polyethylene naphthalate (PEN) film (TEONEX Q65FA, manufactured by Teijin DuPont Films Ltd., thickness: 100 width: 1,000 mm) using a die coater and dried at 50° C. for 3 minutes. Then, the film was irradiated with ultraviolet rays (with a cumulative irradiation dose of about 600 mJ/cm²) and cured to form an organic layer having a thickness of 1 μm.

Using a CVD device, an inorganic layer (silicon nitride layer) was formed on the surface of the organic layer to obtain a gas barrier film. At this time, as raw material gases, silane gas (flow rate of 160 sccm at 0° C. and a standard status of 1 atmospheric pressure, the same will be applied), ammonia gas (flow rate of 370 sccm), hydrogen gas (flow rate of 590 sccm), and nitrogen gas (flow rate of 240 sccm) were used. A high-frequency power supply at a frequency of 13.56 MHz was used as a power supply. The film manufacturing pressure was 40 Pa, and the peak film thickness was 50 nm.

<Formation of Pressure Sensitive Adhesive Layer>

To 10 g of aluminum oxide octylate (OLIEPE AOO, manufactured by Hope Chemical Co., Ltd.), 25 g of dipentaerythrol hexaacrylate DPHA (M405, manufactured by TOAGOSEI CO., LTD.) and 4 g of a polymerization initiator (IRGACURE 819, manufactured by BASF Japan Ltd.) were added, and the mixture was diluted with 60 g of methyl ethyl ketone (MEK) and mixed. The mixture was stirred for 1 hour to prepare 100 g of an adhesive layer forming composition.

The above prepared gas barrier film was placed in a cleaning container and ultrasonically cleaned in pure water. Then, the film was subjected to heating and drying at 120° C. for 120 minutes.

The adhesive layer forming composition was applied to the surface of the inorganic layer of the cleaned gas barrier film using a die coater and dried at 25° C. for 5 minutes to form an adhesive layer. Thus, a sealing member of Example 1 was obtained.

### Example 2

A sealing member of Example 2 was prepared in the same procedure as in Example 1 except that as the monomer of the adhesive layer forming material, instead of using dipentaerythrol hexaacrylate DPHA, 4-hydroxybutyl acrylate glycidyl ether (manufactured by Nippon Kasei Chemical Co., Ltd.) was used.

### Example 3

A sealing member of Example 3 was prepared in the same procedure as in Example 1 except that as the drying agent, instead of using aluminum oxide octylate, aluminum oxide isopropylate (ALGOMAR manufactured by Kawaken Fine Chemicals Co., Ltd.) was used.

### Example 4

A sealing member of Example 4 was prepared in the same procedure as in Example 3 except that as the monomer of the adhesive layer forming material, instead of using dipentaerythrol hexaacrylate DPHA, 4-hydroxybutyl acrylate glycidyl ether (manufactured by Nippon Kasei Chemical Co., Ltd.) was used.

### Comparative Example 1

A sealing member of Comparative Example 1 was prepared in the same procedure as in Example 1 except that as the drying agent, instead of using aluminum oxide octylate, aluminum oxide stearate (OLIEPE AOS, manufactured by Hope Chemical Co., Ltd.) was used.

### Comparative Example 2

A sealing member of Comparative Example 2 was prepared in the same procedure as in Example 2 except that as the drying agent, instead of using aluminum oxide octylate, aluminum oxide stearate was used.

### Comparative Example 3

A sealing member of Comparative Example 3 was prepared in the same procedure as in Example 3 except that as the drying agent, instead of using aluminum oxide isopropylate, aluminum oxide ethylate was used.

### Comparative Example 4

A sealing member of Comparative Example 4 was prepared in the same procedure as in Example 4 except that as the drying agent, instead of using aluminum oxide isopropylate, aluminum oxide ethylate was used.

<Preparation of Organic Electroluminescent Device>

On a 25 mm cornered glass substrate with an ITO (70 nm) electrode, which had been subjected to heating and drying at 120° C. for 120 minutes after ultrasonically cleaning in pure water, hexaazatriphenylene hexacarbonitrile (HATCN) was vacuum-deposited to have a thickness of 10 nm and thus a hole injection layer was formed.

On the hole injection layer, α-NPD(Bis[N-(1-naphthyl)-N-phenyl]benzidine) was vacuum-deposited to have a thickness of 500 nm and thus a first hole transport layer was formed.

On the first hole transport layer, Organic material A represented by the following structural formula was vacuum-deposited to have a thickness of 5 nm and thus a second hole transport layer was formed.

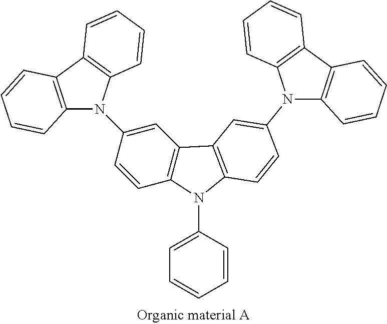 [SMILES: c1ccc(-n2c3ccc(-n4c5ccccc5c5ccccc54)cc3c3cc(-n4c5ccccc5c5ccccc54)ccc32)cc1]

Next, a material doped with Light emitting material A represented by the following structural formula, in which MCP (meta-dicarbazol-9-ylbenzene) is used as a host material and the amount of a phosphorescence light emitting material is 40% by mass with respect to the host material, was vacuum-deposited on the second hole transport layer to have a thickness of 30 nm and thus an organic light emitting layer was formed.

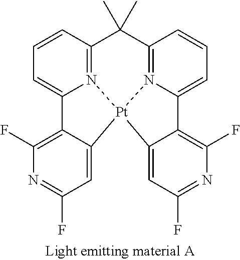

On the organic light emitting layer, BAlq (Bis-(2-methyl-8-quinolinolato)-4-(phenyl-phenolate)-aluminium(III)) represented by the following structural formula was vacuum-deposited to have a thickness of 39 nm and thus a first electron transport layer was formed.

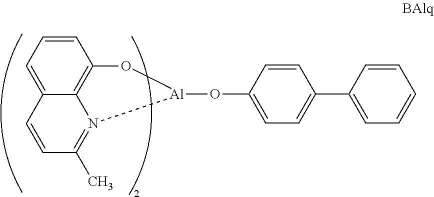

On the first electron transport layer, BCP (2,9-dimethyl-4,7-diphenyl-1,10-phenanthroline) represented by the following structural formula was vacuum-deposited to have a thickness of 1 nm and thus a second electron transport layer was formed.

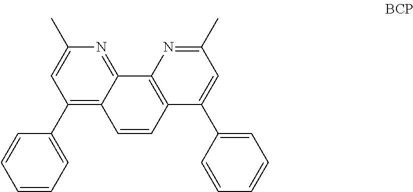 [SMILES: Cc1cc(-c2ccccc2)c2ccc3c(-c4ccccc4)cc(C)nc3c2n1]

On the second electron transport layer, LiF was deposited to have a thickness of 1 nm and thus an electron injection layer was formed.

On the electron injection layer, aluminum was deposited to have a thickness of 100 nm and thus a reflection electrode was formed.

The sealing member prepared as described above was irradiated with 100 mW/cm² of ultraviolet rays (365 nm) in a globe under a nitrogen atmosphere (dew point: −70° C.) for 1 minute to half-cure the adhesive layer. Further, the side of the glass substrate on which the organic EL element was prepared close to the organic layer was bonded to the side of the sealing member closer to the adhesive layer and the organic EL element was sealed by heating at 80° C. for 1 hour and thus an organic electroluminescent device was prepared.

<Evaluation of Organic Electroluminescent Device>

(Temporal Stability)

Using each of the sealing members of Examples 1 to 4 and Comparative Examples 1 to 4 prepared as described above, organic electroluminescent devices as described above were prepared. A temporal change in the organic electroluminescent device was evaluated based on the ratio of dark spots (DS) in the light emitting portion.

Using a SOURCE MEASURE UNIT 2400 manufactured by TOYO-TECHNICA CO., LTD., DC constant voltage was applied to each organic electroluminescent device to have a current value of 2 mA/cm² so as to emit light. The light emitting portion was taken an image and the image was subjected to binarization as image processing with PHOTOSHOP (registered trademark) produced by Adobe Systems Incorporated., which is image processing software. The image was divided into a dark part and a bright part to obtain the ratio of dark spots (DS) by the following expression.

Dark parts in each of Examples and Comparative Examples/Bright parts in each of Examples and Comparative Examples=DS ratio (%)

Each organic electroluminescent device was placed at a temperature of 60° C. and a relative humidity of 90% RH and left to stand for 100 hours. Then, each organic electroluminescent device was evaluated.

(Haze Value)

Regarding the sealing members of Examples 1 to 4 and Comparative Examples 1 to 4, the haze value before the curing of the adhesive layer (initial haze value), and the haze value after the organic electroluminescent device was left to stand for 100 hours at a temperature of 60° C. and a relative humidity of 90% RH after curing in the same manner as in the preparation of the organic electroluminescent device (haze value after time passed) were measured using a haze meter MODEL 1001DP (manufactured by Nippon Denshoku Industries Co., Ltd.).

(Drying Agent Particle Diameter)

The drying agent particle size distribution in the sealing members of Examples 1 to 4 and Comparative Examples 1 to 4 was measured by a dynamic light scattering method using ZETA SIZER NANO-ZS (manufactured by Malvern Instruments), and the average value thereof was used as an average secondary particle diameter.

The evaluation results are shown in Table 1.

TABLE 1

| | | | | | | Sealing | | |
|---|---|---|---|---|---|---|---|---|
| | Pressure sensitive adhesive layer | | | | | perform- | | |
| | | | | | Average | ance | | Haze |
| | | | | | secondary | (DS ratio | | value |
| | | | | | particle | after | Initial | after |
| | Polymerizable | | | Sp value | diameter | time | haze | time |
| | compound | Sp value | Drying agent | of ROH | (nm) | passed) | value % | passed % |
| Example 1 | Acrylate | 10.1 | —[Al(OR)-O]ₙ— | 8.8 | 80 | <1% | 0.2 | 1 |
| | | | (OLIEPE AOO) | | | | | |
| | | | R: C₄H₉(C₂H₅)CHCO | | | | | |
| Example 2 | Epoxy | 10.3 | —[Al(OR)-O]ₙ— | 8.8 | 60 | <1% | 0.2 | 1 |
| | acrylate | | (OLIEPE AOO) | | | | | |
| | | | R: C₄H₉(C₂H₅)CHCO | | | | | |
| Example 3 | Acrylate | 10.1 | —[Al(OR)-O]ₙ— | 11.5 | 50 | <1% | 0.2 | 1 |
| | | | (ALGOMAR) | | | | | |
| | | | R: (CH₃)₂CH | | | | | |
| Example 4 | Epoxy | 10.3 | —[Al(OR)-O]ₙ— | 11.5 | 80 | <1% | 0.3 | 2 |
| | acrylate | | (ALGOMAR) | | | | | |
| | | | R: (CH₃)₂CH | | | | | |
| Comparative | Acrylate | 10.1 | —[Al(OR)-O]ₙ— | 8.4 | 130 | 4% | 0.5 | 11 |
| Example 1 | | | (OLIEPE AOS) | | | | | |
| | | | R: C₁₇H₃₅ | | | | | |
| | | | (Stearic acid) | | | | | |
| Comparative | Epoxy | 10.3 | —[Al(OR)-O]ₙ— | 8.4 | 150 | 4% | 2.4 | 20 |
| Example 2 | acrylate | | (OLIEPE AOS) | | | | | |
| | | | R: C₁₇H₃₅ | | | | | |
| | | | (Stearic acid) | | | | | |
| Comparative | Acrylate | 10.1 | —[Al(OR)-O]ₙ— | 12.6 | 200 | Not | 1.4 | 12 |
| Example 3 | | | R: CH₃CH₂ | | | lightable | | |
| Comparative | Epoxy | 10.3 | —[Al(OR)-O]ₙ— | 12.6 | 250 | 6% | 1.7 | 16 |
| Example 4 | acrylate | | R: CH₃CH₂ | | | | | |

What is claimed is:

1. An organic electronic device sealing member comprising:
a gas barrier film; and
an adhesive layer,
wherein the gas barrier film includes a barrier laminate including at least one inorganic layer and at least one organic layer, and the adhesive layer includes a polymerizable compound and an organic metal compound,
an average secondary particle diameter of the organic metal compound is 100 nm or less, and
the organic metal compound has a structure represented by Formula I:
-[M(OR)—O]n- Formula I
in Formula I, M represents a trivalent metal atom, R represents a substituted or unsubstituted alkyl group, a substituted or unsubstituted aryl group, or a substituted or unsubstituted alkylcarbonyl group, n represents an integer of 2 to 6, two or more R's may be the same as or different from each other, and a first [M(OR)—O] and an n-th [M(OR)—O] are bonded to each other.

2. The organic electronic device sealing member according to claim 1,
wherein n R's are all the same.

3. The organic electronic device sealing member according to claim 1,
wherein M is Al.

4. The organic electronic device sealing member according to claim 1,
wherein the polymerizable compound is a (meth)acrylate.

5. The organic electronic device sealing member according to claim 1,
wherein the gas barrier film includes a substrate film, and the barrier laminate is arranged on the side of the substrate film close to the adhesive layer.

6. The organic electronic device sealing member according to claim 1,
wherein the at least one inorganic layer is in direct contact with the adhesive layer.

7. The organic electronic device sealing member according to claim 1,
wherein an organic layer closest to the adhesive layer is a layer formed by curing a polymerizable composition including (meth)acrylate.

8. The organic electronic device sealing member according to claim 1,
wherein n R's are all the same, M is Al, the polymerizable compound is a (meth)acrylate, the at least one inorganic layer is in direct contact with the adhesive layer, and an organic layer closest to the adhesive layer is a layer formed by curing a polymerizable composition including (meth)acrylate.

9. The organic electronic device sealing member according to claim 8,
wherein the polymerizable compound is dipentaerythrol hexaacrylate and the organic metal compound is aluminum oxide octylate.

10. The organic electronic device sealing member according to claim 9,
wherein the mass ratio of the polymerizable compound and the organic metal compound is 25:10.

11. The organic electronic device sealing member according to claim 8,
wherein the polymerizable compound is dipentaerythrol hexaacrylate and the organic metal compound is aluminum oxide isopropylate.

12. The organic electronic device sealing member according to claim 1,
wherein n R's are all the same, M is Al, the polymerizable compound is an epoxy compound, the at least one inorganic layer is in direct contact with the adhesive layer, and an organic layer closest to the adhesive layer is a layer formed by curing a polymerizable composition including (meth)acrylate.

13. The organic electronic device sealing member according to claim 12,
wherein the polymerizable compound is 4-hydroxybutyl acrylate glycidyl ether and the organic metal compound is aluminum oxide octylate.

14. The organic electronic device sealing member according to claim 13,
wherein the mass ratio of the polymerizable compound and the organic metal compound is 25:10.

15. The organic electronic device sealing member according to claim 12,
wherein the polymerizable compound is 4-hydroxybutyl acrylate glycidyl ether and the organic metal compound is aluminum oxide isopropylate.

16. The organic electronic device sealing member according to claim 1,
wherein R forms ROH having an Sp value in a range of 8.5 to 12 (cal/cm³)^{1/2}.

17. The organic electronic device sealing member according to claim 1,
wherein an Sp value of the polymerizable compound is 8.5 to 12 (cal/cm³)^{1/2}.

18. The organic electronic device sealing member according to a claim 1,
wherein a difference between the Sp value of ROH that R forms and the Sp value of the polymerizable compound is 2 (cal/cm³)^{1/2} or less.

19. The organic electronic device sealing member according to claim 1,
wherein the adhesive layer is a layer composed of a polymerizable composition including the polymerizable compound, the organic metal compound, and a solvent, and an Sp value of the solvent is 8.5 to 12 (cal/cm³)^{1/2}.

20. The organic electronic device sealing member according to claim 1,
wherein the adhesive layer is a layer composed of a polymerizable composition including the polymerizable compound, the organic metal compound, and a solvent, and both a difference between the Sp value of the solvent and the Sp value of ROH that R forms and a difference between the Sp value of the solvent and the Sp value of the polymerizable compound are 2 (cal/cm³)^{1/2} or less.
